(19) United States
(12) Patent Application Publication
(10) Pub. No.: US 2018/0241503 A1
(43) Pub. Date: Aug. 23, 2018

(54) SYSTEMS AND METHODS FOR SPACE-BASED AND HYBRID DISTRIBUTED DATA STORAGE

(71) Applicant: SEAKR ENGINEERING, INC., CENTENNIAL, CO (US)

(72) Inventor: W. Reagan Harper, Centennial, CO (US)

(21) Appl. No.: 15/897,927

(22) Filed: Feb. 15, 2018

Related U.S. Application Data
(60) Provisional application No. 62/460,456, filed on Feb. 17, 2017.

(51) Int. Cl. H04L 1/00; H03M 13/15; H04L 29/08

(52) U.S. Cl. CPC H04L 1/0041; H04L 1/0045; H04L 67/1097; H03M 13/154; H04L 1/0058

(57) ABSTRACT

Systems and methods for implementing robust, reliable distributed data storage across satellites and or among terrestrial and space-based assets are described. In some examples, data is erasure encoded prior to storage to improve reliability while minimizing storage capacity requirements. In some examples, erasure encoded data is stored across a combination of satellites and terrestrial assets in a manner that prohibits reconstruction of the data using only encoded data on the ground. In some examples, an erasure encoding fragment size is selected based on a write page size of a solid state device to extend device life.

### CROSS-REFERENCE TO RELATED APPLICATION(S)

The present application claims priority to pending U.S. Provisional Application No. 62/460,456, filed on Feb. 17, 2017, and incorporated herein by reference in its entirety.

### TECHNICAL FIELD

The present disclosure relates generally to systems and methods for implementing distributed data storage in space, and more specifically to providing cloud storage in space using satellites.

### BACKGROUND

Cloud storage is a model of distributed data storage in which digital data is stored in logical pools. The physical storage often spans multiple servers (and often locations), and the physical environment is typically owned and managed by a hosting company. In recent years, a variety of market factors have begun to drive the effort to build a space-based cloud storage network in which at least some of the storage assets are located in satellites. These factors include a desire for better data security, reduced exposure to ground-based natural disasters, independence from the security challenges associated with the Internet, and more favorable jurisdictional regulations. However, placing bulk storage in a space environment adds challenging requirements to the storage architecture due to differences in hardware requirements and constraints for space-based applications relative to ground-based applications, along with a lack of infrastructure (e.g., Internet) for implementing distributed server-based systems across satellites.

The ability to recover or reconstruct data stored on in satellites and other space-based vehicles is highly desirable due to, among other things, the effects of radiation on space-based electronics including data storage devices based on flash memory and other solid-state storage technologies. In particular, radiation effects in space can cause data corruption by causing bits to flip, storage device controllers to operate incorrectly, transmission and reception of data signals to be distorted or lost, and the like. Data redundancy is one way to ensure the ability to recover and reconstruct data, but can have an undesirable effect on the design and operation of the spacecraft in terms of size, weight, power, and power (SWAP). That is, in order to allow for recovery or reconstruction of corrupted, missing, or incomplete data, often a certain level of redundancy is needed. In the case of duplication of data (e.g., 100% redundancy), twice the storage capacity, storage density, controllers, and/or storage devices are needed. However, minimizing launch costs, power requirements, design complexity, operational efficiency and costs is highly desirable as these considerations all impact the ability of the user to generate revenue. Providing redundant data capacity, in the form of additional storage devices and storage capacity, is often contrary to these goals since it can dramatically increase SWAP and cost of the satellite or other space-based asset.

One way to reduce storage overhead is to implement erasure codes. An erasure code is a forward error correction (FEC) code under the assumption of bit erasures (rather than bit errors), which transforms a message of m symbols into a longer message (code word) with n symbols such that the original message can be recovered from a subset of the n symbols. The fraction r=min is called the code rate. In some examples, erasure coding storage overheads in the range of 25%-100% are desirable. Exemplary discussions may be found in Elastic Erasure Coding for Adaptive Redundancy by Wan Hee Cho and Anwitaman Datta published in the 2016 IEEE 36th International Conference on Distributed Computing Systems Workshops, which is incorporated herein by reference in its entirety.

Accordingly, systems and methods for implementing robust distributed data storage in space are desirable, while allowing for data recovery with minimal storage overhead and/or with minimal redundant storage capacity.

### SUMMARY

In some examples, a system for implementing distributed data storage in space comprises a first satellite that includes a receiver configured to receive data, a transmitter configured to transmit data, and a storage subsystem configured to store data; and a first set of one or more processing subsystems, each processing subsystem configured to: receive a data set, divide the data set into m fragments, encode the m fragments into n encoded fragments, wherein 1<m<n, and wherein the data set can be reconstructed using m of the n encoded fragments, and transmit a first portion of the n encoded fragments to the first satellite, wherein the first satellite is configured to store the portion of the n encoded fragments in the storage subsystem.

In some examples, a method for implementing distributed satellite-based data storage, comprises receiving a data set; splitting the data set into m fragments; encoding the m fragments into n encoded fragments, wherein 1<m<n, and wherein the data set can be reconstructed using m of the n encoded fragments; transmitting a first portion of the n encoded fragments to a first satellite; storing the first portion of the n encoded fragments on a storage subsystem on the first satellite, transmitting a second portion of the n encoded fragments to a second satellite; and storing the second portion of the n encoded fragments on a storage subsystem on the second satellite.

### BRIEF DESCRIPTION OF THE DRAWINGS

FIG. 1 depicts an exemplary satellite-based cloud storage system.

FIG. 2 depicts an exemplary partitioning of erasure encoded data across satellites.

FIG. 3 depicts an exemplary partitioning of erasure encoded data across satellites and terrestrial or ground-based storage systems.

FIG. 4 depicts an exemplary satellite payload.

FIG. 5 depicts an exemplary method for implementing distributed satellite-based data storage.

FIG. 6 depicts an exemplary simplified processing subsystem.

### DETAILED DESCRIPTION

Distributed satellite-based data storage that is analogous to ground-based terrestrial cloud storage is desirable for a variety of reasons, as described above. However, directly replicating a terrestrial cloud storage model in space is not feasible due to differences in both the hardware requirements and constraints, and due to the lack of existing infrastructure on satellites to support a cloud-based distributed storage approach. For example, there is no equivalent to the Internet in space, and unlike terrestrial cloud storage the use of hard disk drives (HDDs), which generally have large storage capacities, has many drawbacks when implemented in space.

The high cost of launching space assets requires that the size, weight, and power (SWAP) of hardware used in space is optimized not only at the spacecraft level, but also at the satellite constellation level. However, given the difficulty of performing hands-on maintenance, space-based systems must also be highly reliable, a requirement that is in conflict with the need to minimize the system's size and weight since providing reliability without hands-on maintenance generally leads to some level of hardware redundancy. In particular, space-based electronics are particularly prone to interruption, corruption, and failure modes due to the ionizing radiation environment experienced in space. Without utilizing specific techniques to compensate or correct for these radiation effects, space-based electronics can be placed into an inoperable mode, have user and configuration data corrupted or lost, and in worst-case examples can cause irreversible damage to the electronics system. By providing a certain level of hardware redundancy, and/or designing the electronics to be radiation-tolerant by design or by process, these effects can be mitigated and impact on the mission, operability of the satellite, and negative impact on revenue generation can be minimized. However, adding hardware redundancy, such as increased storage capacity or additional storage devices, runs counter to minimizing SWAP. Accordingly, it is desirable to reduce the level of redundancy necessary to ensure data integrity, recoverability of data, and ensure continued operation of the satellite per mission and user requirements.

The worst-case redundancy with respect to size and weight is block-level redundancy; in which the same block of data is stored in multiple storage subsystems. In this case, whole storage subsystems are typically flown in cold standby (e.g., receiving scheduled backups of the primary subsystems) so that if a failure occurs in a primary storage subsystem the system can switch to its redundant storage subsystem and remain fully operational. For example, a system with a storage subsystem made up of two memory boards would have another two-memory-board subsystem that is flown in cold standby and could be used if the first subsystem failed.

Another approach is to use shared redundancy, in which only a portion of the storage subsystem is provided with redundancy. For example, the same two-memory-board subsystem might include a third memory board in case one of the primary memory boards failed. A shared redundancy system can require fewer resources to provide similar reliability, which generally equates to a smaller overall system size and lower weight.

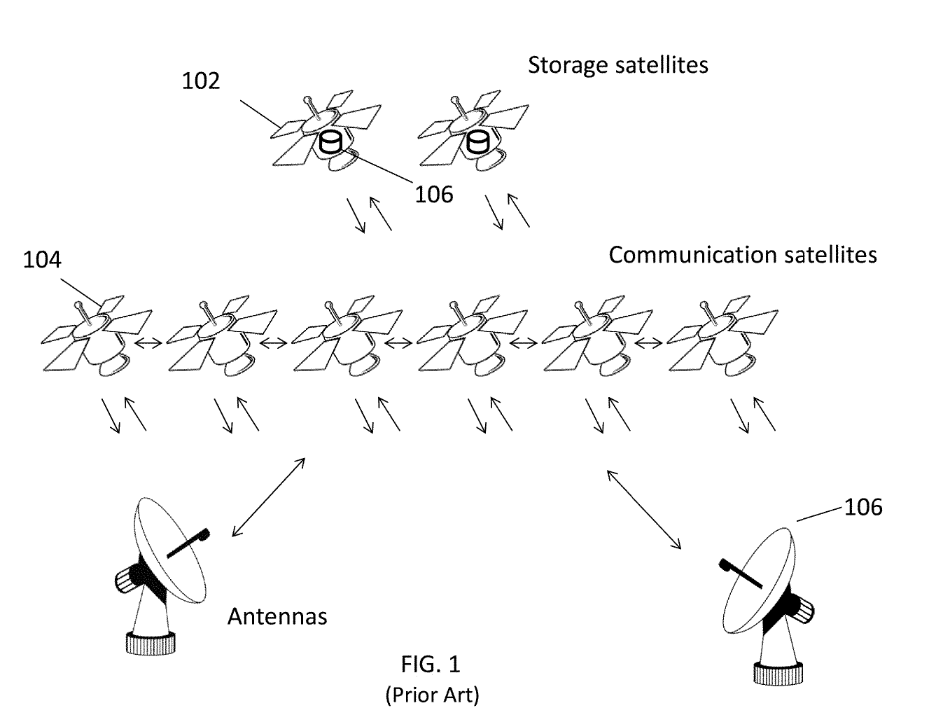

Without the use of erasure coding as described in the present disclosure, a satellite-based cloud storage system might be implemented using full block-level redundancy in a manner such as depicted in FIG. 1. The exemplary system depicted in FIG. 1 includes two storage satellites 102, each with (for example) 1 PB of storage, for a total of 2 PB. The data 106 stored on each of the two storage satellites is identical.

Earth-to-satellite communication typically requires line-of-sight propagation, and thus the exemplary system of FIG. 1 also includes six communications satellites 104 that may relay data from the storage satellites to Earth, potentially by way of geosynchronous satellites (not shown). Here, a communications satellite 104 may relay data to other communications satellites 104 until the data reaches a satellite that is in an appropriate location to communicate with Earth. Note that in the system depicted in FIG. 1, typically only one communication satellite is transmitting/receiving data to/from Earth at a time, based on the location of the terrestrial antenna to which data is being transmitted/received.

Because the approach depicted in FIG. 1 requires complete data duplication, there is high overhead in terms of the amount of data that must be stored and the corresponding storage hardware required by the satellites. Furthermore, the total amount of storage is limited by the size, weight, and power constraints of the storage satellites and the size of available solid state drives.

In contrast, systems and methods described in the present disclosure utilize erasure coding of a data set and distribute the data across one or more satellites and/or terrestrial assets to provide appropriate levels of redundancy while reducing system size, weight, and power of the space-based assets. As will be discussed, erasure coding allows for in some cases as much as 75% reduction in the amount of storage overhead required to allow for corrupted or deleted data to be recovered.

Implementing a large-scale distributed storage system in space may require multiple petabytes (PBs) of storage in order to justify the high costs associated with building and launching the satellites. However, as previously noted, a satellite-based distributed data storage system must operate within different hardware constraints than a terrestrial distributed storage system. While ground-based or terrestrial distributed storage currently consumes hundreds of petabytes (PB) of storage, even a 1 PB storage system on a satellite is beyond today's state of the art due to limitations in current storage technologies. For example, mechanical drives including hard disk drives (HDDs), such as those used for terrestrial distributed data storage, are not practical for space applications for a variety of reasons: they have low rates of launch survival, they impart rotational velocity to the satellite host, they are air cooled, etc. Instead, space applications often rely on flash memory, which are solid state memory devices that are used in space for non-volatile storage applications. However, many of the high-capacity the flash devices that are currently used in space (e.g., devices that are radiation-tolerant) do not presently have the density required to make a 1 PB or greater memory system within typical satellite size, weight, and power constraints, although such high-capacity and/or high-density flash devices would be compatible with and usable in systems and methods described in the present disclosure. The only devices that are available in densities that can support a 1 PB system are packaged in solid state drives (SSDs). A 1 PB system, though, would require at least 64 solid state drives, if using current state-of-the-art 16 TB drives. But this implementation does not allow for any redundant drives that may be required to meet reliability specifications. In addition, some systems may require full satellite-level redundancy in case an entire satellite fails, compounding the storage challenge.

Exemplary systems and methods disclosed herein are based on the use of cross-satellite erasure coding to provide robust and reliable data storage in space without requiring the additional storage devices needed for duplicating data on different satellites. Furthermore, in some examples, the disclosed systems and methods may implement erasure-coded distributed data storage using a combination of terrestrial storage and satellite-based storage to further reduce the storage requirements on the satellites while providing the benefits of space-based cloud storage described earlier. The number of satellites and the storage capacity requirements for each satellite may vary in accordance with the operational requirements of the distributed data system. As additional satellite and/or terrestrial assets are added to the system, the erasure-encoded data may be adapted for storage across the new and/or replacement storage assets, such as when a constellation of satellites is being built over a plurality of satellite launch cycles.

Erasure coding is a method of data protection in which data is broken into fragments (sometimes called shards or chunks), expanded and encoded with redundant data pieces to form encoded fragments, and stored across one or more storage devices. According to the present disclosure, erasure coding may be used within a single satellite to overcome single event upsets (SEUs) in memory devices caused by radiation, and to overcome other types of device-level failures such as device latch-up, leakage failures, mechanical failures, etc. In other examples of the present disclosure, erasure coding may be performed for data storage across multiple satellites such as a constellation of satellites, and may also be performed for data storage among one or more satellites and terrestrial assets. While erasure coding is sometimes referred to as a form of error correction, it can be used to address a different problem. For example, forward error correction techniques typically address the problem of identifying and correcting random, unknown errors that may occur during data transmission. Erasure coding, in contrast, can be used to help recover data after a storage device has suffered a (known) erasure, corruption, or other types of data loss.

Memory architectures that use erasure codes can recover the original data even if two devices completely fail in each memory address, while requiring in some examples as little as 25% overhead (i.e., requiring approximately 25% more storage or more devices relative to the number required to store the data without redundancy). Using erasure codes, a system that employs in some examples only 25% more memory can provide similar reliability to a system that doubles the storage requirements. This can have significant advantages when employed in a satellite data storage system, as it can reduce the number of storage devices and/or the capacity of the storage devices by as much as 75% which directly impacts the size, weight, power, and cost (SWAPC) of the satellite payload. In some implementations where there is a constellation of many satellites, the SWAPC optimization afforded by the erasure coding of the present disclosure has even more impact on a mission. Of course, including additional erasure coded overhead greater than 25% can increase the reliability still further, while still allowing for significant savings in size, power, weight, and cost.

In erasure coding, a data set is divided into m fragments. The m fragments are encoded using erasure coding into n encoded fragments, where n>m>1. The original data set can then be reconstructed from any m encoded fragments. The larger n is, the greater the reliability of the system due to the increase in redundancy, at the expense of requiring greater storage capacity. The satellite-based distributed data storage system of the present disclosure may implement erasure coding using Reed-Solomon (RS) codes, Tornado codes, fountain codes, turbo codes, Low Density Parity codes, or other suitable erasure codes. A satellite-based distributed data storage system may determine which erasure code to use based on the desired reliability, the number of available satellites, the computational resources available, and/or the available storage, for example.

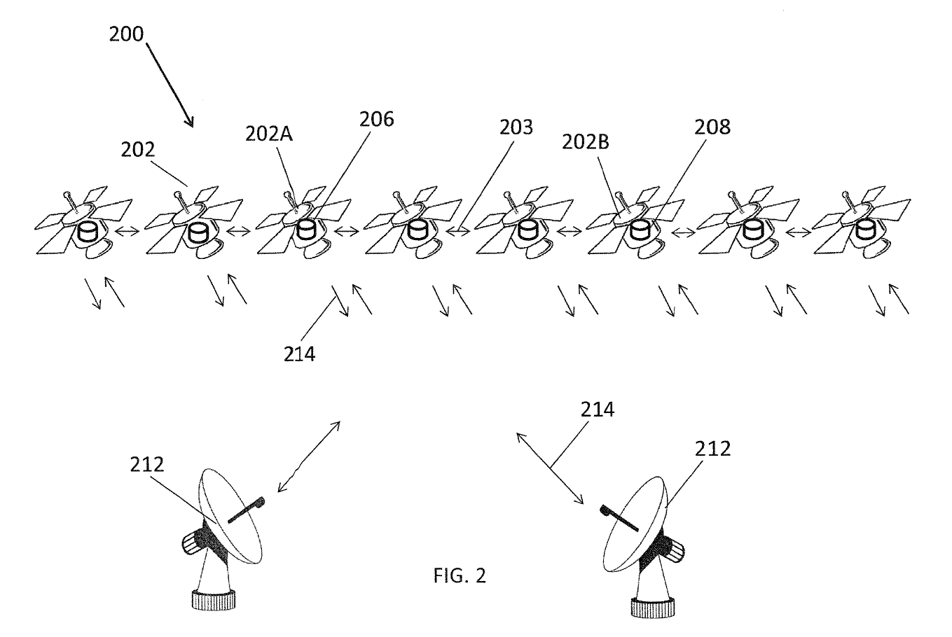

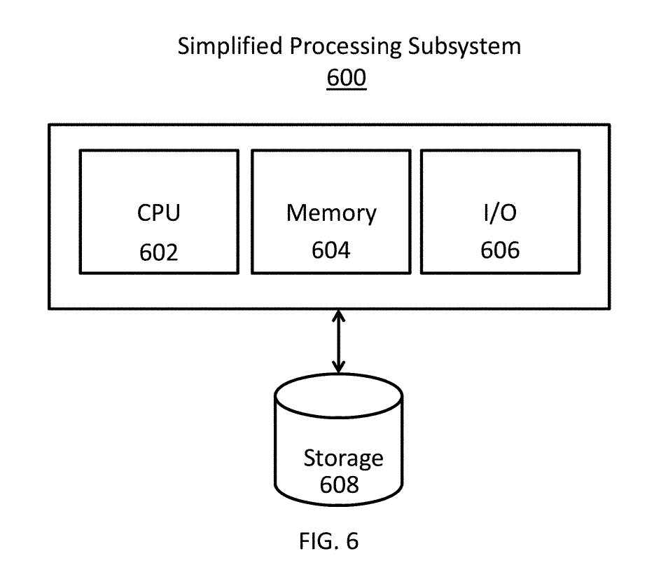

In one example of the present disclosure, FIG. 2 illustrates a satellite-based distributed data storage system 200 which may employ erasure coding as discussed above to store encoded data across multiple satellites 202. Each of the satellites 202 may include at least one storage device for storing raw data sets and/or erasure-encoded data sets and a processing subsystem, such as the simplified processing subsystem 600 described below with respect to FIG. 6, to allow the satellites 202 to transmit, receive, store, encode, and decode information and data in accordance with the examples of the present disclosure. Accordingly, each of the satellites 202 depicted In FIG. 2 may be capable of receiving and transmitting one or more data sets from Earth or other terrestrial assets 212 over a link 214 as well as to and from another satellite 202 via inter-satellite links 203. Communication links 214 may be formed using conventional radio frequency (RF) signals and the satellites 202 may receive or transmit data using antennas or antenna arrays that function as receivers or transmitters, or may be other types of wireless communication signals such as optical signals, for example. In some examples, communication links 214 may operate in the E band, L band, S band, C band, X band, Kᵤ band, K band, Kₐ band, and V bands.lnter-satellite communication links 203 may also be formed by RF signals and antenna systems similar to links 214, or in some examples may employ optical transceiver modules to receive and/or transmit data signals between the satellites 202, such as for example laser-based or other photonic communication systems. Terrestrial assets 212 capable of transmitting and receiving one or more data sets, as well as in some examples processing, encoding, decoding, and storing data sets, may include ground-based antennas, ground-based satellite dishes, other types of ground stations or gateways, high-altitude assets such as balloons or tethered transceivers, autonomous or unmanned aerial vehicles, drones, piloted aircraft, and the like. Terrestrial assets 212 may therefore include processors, memory for storing instructions for being executed by the processor, and storage for storing at least a portion of the data of the distributed storage system 200.

In the system depicted in FIG. 2, each of the eight satellites 202 may store a portion of erasure encoded data set. In some examples the portions may include different subsets of erasure coded data fragments, where the subsets may be the same number of fragments or may include a varying number of fragments per satellite depending on available storage capacity of the satellite 202. For example, as shown in FIG. 2, one satellite 202A may store a first portion 206 of the n encoded fragments on a storage device of the satellite 202A, while another satellite 202B may store a second portion 208 of the n encoded fragments on a storage device of the satellite 202B, and so on.

Using erasure coding, the system 200 may reduce the total amount of data storage required in order to provide a desired level of reliability. In the exemplary system 200 depicted in FIG. 2, instead of providing two storage satellites with 1 PB of data and six communications-only satellites (such as in the system of FIG. 1), the system 200 may include eight satellites 202, each with 160 TB of storage (for 1.3 PB total) and communications capabilities. It is noted that the satellites 202 may serve as multi-purpose satellites and operate as both communications and storage satellites. In some examples, however, the satellites 202 may operate primarily as storage satellites, while in other examples the primary operation may be for communications, Earth or space imagery, scientific investigation, reconnaissance purposes, and the like, while also providing storage capacity in the distributed data storage system 200. It is noted that in some examples, the satellites 202 may store redundant copies of n fragments or a subset of n fragments depending on particular needs and uses of the system 200. It is noted that although the system 200 has been discussed as having eight satellites 202, the present disclosure is not limited to this and the system 200 may comprise more or fewer than eight satellites 202. In some examples, the system 200 may comprise a constellation or a swarm of satellites 202 comprising thirty or more satellites 202.

In some examples, such a system may provide similar reliability as provided by the system depicted in FIG. 1, but with a significant reduction in the total amount of storage. For example, compared with the system of FIG. 1, the total storage of the system 200 may be reduced from 2 PB to 1.3 PB and the corresponding size of the required storage hardware on each satellite reduced to (for example) ten 16 TB solid state drives. Such storage hardware can be accommodated within typical satellite constraints, and is small enough to be included on a satellite that also includes communications hardware. Thus, while the total number of satellites 202 depicted in the example of FIG. 2 may be the same as depicted in the block-level redundancy system 100 described with respect to FIG. 1, the reliability of the system may be similar (or even better) than that provided by the system depicted in FIG. 1. Each satellite 202 may be able to communicate directly with ground-based or terrestrial assets 212, which may reduce data transmission latencies. It is also noted, however, that if a satellite 202 cannot directly communicate with terrestrial assets 212, the inter-satellite link(s) 203 may allow for a satellite 202 to communicate data to another satellite 202 which has line of sight to a terrestrial asset 212.

As previously noted, systems for implementing distributed data storage on satellites may be conceptually similar to ground-based cloud storage, but it is not possible to directly replicate the ground-based cloud storage in space, for several reasons. First, satellite communications and storage systems are not designed to provide an infrastructure that is similar to the Internet. Satellite communications systems are most often proprietary systems with protocols that have been optimized for communication links with both high latency and high bit error rates. Internet protocols such as TCP/IP are notoriously bad for these types of links and are thus not generally appropriate for communication with space-based servers. The typical space architecture employs servers on the ground with space assets that act as non-autonomous slaves. Thus, implementing distributed data storage in space requires replacing the TCP/IP and standard cloud-based server concepts with the appropriate space-based protocols, satellite identification protocols, and failure recognition and recovery mechanisms appropriate for a space asset network. In some examples, a space-based data storage system must also be able to integrate with standard ground-based protocols so that ground-based assets can be included in the storage network in order to increase reliability.

Erasure coding has several advantages for space-based data storage relative to other types of fault tolerance used for ground-based applications, such as RAID (redundant array of independent disks). In RAID, the data is replicated across multiple drives. However, in several common RAID configurations if a single drive develops faulty sectors in a RAID configuration, the whole RAID-set must be reformatted to remove the faulty sectors. A typical recovery time for a RAID set with 16 TB drives (such as might be used on a satellite) would be on the order of 5 or more days. In typical commercial satellites, which can generate very high monthly and annual revenues, this amount of downtime would have a significant financial impact on the operator as well as a significant impact on end users. Since flash-based SSDs have a comparatively high sector failure rate compared to a typical spinning hard drive, system down time due to the use of a RAID reconfiguration would unacceptably impact system availability. Furthermore, using RAID in a space-based application would require the use of radiation-tolerant RAID controller hardware, which may be expensive, add to design complexity, and have high size, power, and weight. Even 16 drives per controller would require 32 controllers, adding to the satellite's required size, weight, and power. Furthermore, a large number of drives per controller (e.g., 16) may increase the likelihood of a write failure.

For systems that rely on flash memory-based devices, the erasure coding approach dramatically increases system availability since reformatting is not required when flash sectors fail. With erasure encoding, the failed sector can be recreated by decoding the other erasure coded segments and subsequently rewritten to a good portion of the flash-based storage. Furthermore, using erasure coding to meet reliability requirements reduces the amount of hardware relative to both a block-level redundancy and a RAID approach, at the cost of increased computational complexity. In some examples the computational complexity may be managed by terrestrial computing resources to avoid burdening satellites with additional processing hardware. In other examples, the computational burden of implementing erasure codes may be divided among terrestrial and satellite-based processing systems or subsystems, and/or among a plurality of satellite processing subsystems. In still other examples, erasure coding may be performed entirely by processing subsystems provided on the satellites. Accordingly, the data being distributed in the distributed data storage of the present disclosure may be erasure coded using terrestrial assets, satellite assets, or a combination of satellite and terrestrial assets.

Another advantage of erasure coding for flash-based SSDs (and therefore, for satellite-based distributed storage systems) relative to RAID or other approaches is that the erasure code can be tailored to match the natural write page size of the storage hardware used in the SSDs. As described in more detail later, such an approach may reduce the wear on the storage elements of the SSD memory components, a consideration that is particularly important for space-based storage due to the lack of hardware accessibility for maintenance.

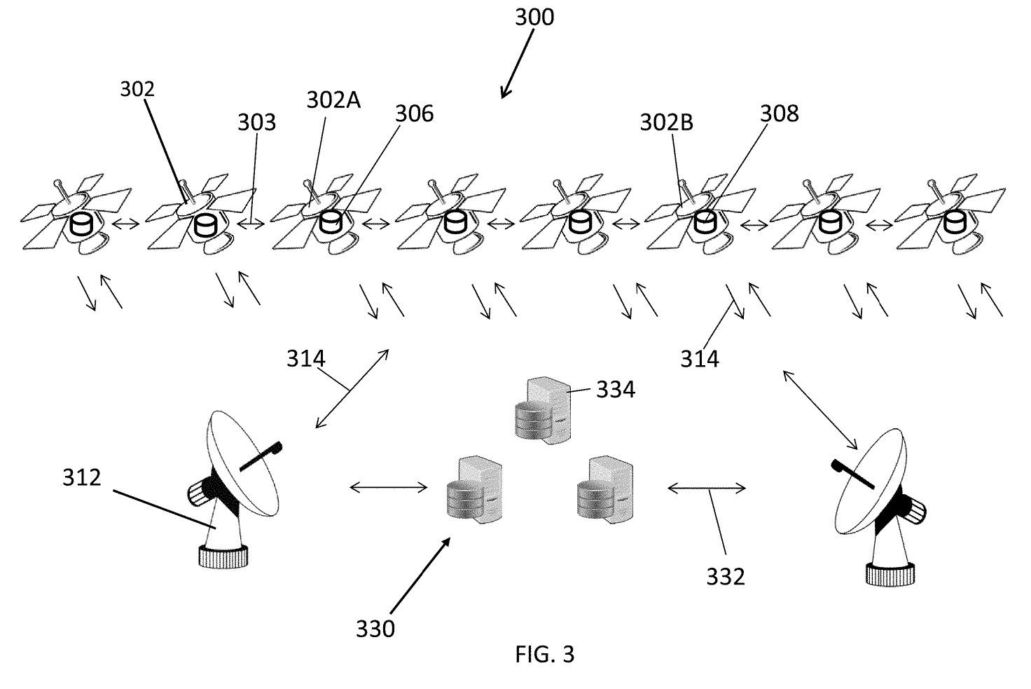

As depicted in FIG. 3, in some examples, erasure coding can also be used to ensure data security and access to data with a hybrid space/terrestrial distributed storage approach. Similar to the system 200 described above in FIG. 2, each of the eight satellites 302 in the distributed storage system 300 may store a portion of erasure encoded data set. In some examples the portions may include different subsets of erasure coded data fragments, where the subsets may be the same number of fragments or may include a varying number of fragments per satellite depending on available storage capacity of the satellite 302. It is noted that in some examples, the satellites 302 may store redundant copies of n fragments or a subset of n fragments depending on particular needs and uses of the system 300.

Each of the satellites 302 may include at least one storage device for storing raw data sets and/or erasure-encoded data sets and a processing subsystem, such as the simplified processing subsystem 600 described below with respect to FIG. 6, to allow the satellites 302 to transmit, receive, store, encode, and decode information and data in accordance with the examples of the present disclosure. Accordingly, each of the satellites 302 depicted In FIG. 3 may be capable of receiving and transmitting at least one data set from Earth or other terrestrial assets 312 over a link 314 as well as to and from another satellite 302 via inter-satellite link(s) 303. Communication links 314 may be formed using conventional radio frequency (RF) signals and the satellites 302 may receive or transmit data signals using antennas or antenna arrays that function as receivers or transmitters, or may receive and transmit signals using other types of wireless communications signals such as optical signals, for example. In some examples, communication links 314 may operate in the E band, L band, S band, C band, X band, Kᵤ band, K band, Kₐ band, and V bands. Inter-satellite communication links 303 may also be formed by RF signals and antenna systems similar to links 314, or in some examples may employ optical transceiver modules to receive and/or transmit data between the satellites 302 using other types of receivers or transmitters, such as for example laser-based or other photonic communication systems. Terrestrial assets 312 capable of transmitting and receiving at least one data set, as well as in some examples processing, encoding, decoding, and storing data sets, may include ground-based antennas, ground-based satellite dishes, other types of ground stations or gateways, high-altitude assets such as balloons or tethered transceivers, autonomous or unmanned aerial vehicles, drones, piloted aircraft, and the like. Terrestrial assets 312 may therefore include processors, memory for storing instructions for being executed by the processor, and storage for storing at least a portion of the one or more data of the distributed storage system 300.

Similar to the system 200 discussed above, the distributed data storage system 300 depicted in FIG. 3 may in one example include eight satellites 302 that each store a portion of erasure encoded data. In some examples the portions may include different subsets of erasure coded data fragments, where the subsets may be the same number of fragments or may include a varying number of fragments per satellite 302 depending on available storage capacity of the satellite 302. For example, as shown in FIG. 3, one satellite 302A may store a first portion 306 of the n encoded fragments on a storage device of the satellite 302A, while another satellite 302B may store a second portion 308 of the n encoded fragments on a storage device of the satellite 302B, and so on. The distributed data storage system 300 may further include terrestrial storage assets 330 and a third portion 334 of the n encoded fragments may be stored in the terrestrial storage assets 330. In some examples, the third portion 334 may include m-1 encoded fragments to ensure data cannot be recovered without at least one fragment from a satellite 302, while in other examples the third portion 332 may include n-m fragments to provide only enough data fragments terrestrially to enable reconstruction of fragments stored on satellites 302. However, these are merely exemplary and the first, second, and third portions 306, 308, 330 may be any size or proportion of the total erasure coded fragments n. Terrestrial assets 312 may be communicatively coupled to the terrestrial storage assets 330 via communication link 332, which may be wireless, wired, optical, and the like. Alternatively, the terrestrial storage assets 330 may have dedicated transceivers (not shown) for communicating directly with one or more satellites 302.

By storing some of the data on the ground, but not enough to allow an attacker that gains access to the terrestrial assets 312, 330 to reproduce the data, such a hybrid distributed data storage system can potentially provide the benefits of space-based storage (e.g., relative immunity from attacks/hacking and terrestrial natural disasters, control over which jurisdictions data crosses, etc.) without requiring all of the data to be stored in place, thereby reducing the cost of implementing satellite-based cloud storage. In this approach, some of the encoded fragments are stored in space while some are stored on the ground.

The hybrid space/ground cloud storage approach enables some interesting encoding optimizations that trade off factors such as security, cost, and latency. For example, since m encoded fragments are required to reconstruct a data set, it is possible to ensure that the data set cannot be reconstructed from the fragments stored on the ground if the number of fragments stored on the ground is restricted to be fewer than m (e.g., ≤m-1). Thus, in some examples the encoding software or encoding algorithm, which may also be hardware-implemented, can ensure that the data set is protected from ground-based attacks by limiting the amount of data stored on the ground.

In some examples the encoding software can maximize the number of encoded fragments that are stored on the ground (since ground storage is generally cheaper and easier to maintain than satellite storage) within the constraint that the data set cannot be reconstructed using only terrestrial data. For example, if m encoded fragments are required to reconstruct the data set as discussed above, the encoding software can ensure that m-1 encoded fragments are stored on the ground. Such a ground-centric approach may have the added benefit of reducing data retrieval latencies since less of the data must be retrieved from space (and depending on how close the relevant ground- or terrestrial-based storage assets are to the device requesting data).

In some examples, the encoding software can ensure that a sufficient number of encoded fragments are stored in space such that the data set can be reconstructed from space-only encoded fragments (i.e., without requiring the use of the encoded fragments stored on the ground.) In this case, there may be m fragments stored in space, and n-m encoded fragments stored on the ground. Note, however, the data can only be reconstructed from space if at least m encoded fragments are available in space. If any of the space-based fragments have been damaged, then the system could still reconstruct the data set using the terrestrial encoded data. Thus, while not necessarily required for reconstructing the data set, the terrestrial data may provide additional redundancy without increasing security risk. In an analogous example to the ground-centric approach discussed above, some examples of such a satellite-centric approach may maximize the number of fragments stored in space. For example, the distributed data storage system may be configured to store m-1 fragments in space to ensure that data cannot be recovered without using at least some data fragments from terrestrial storage assets.

To extend the life of the target SSDs used to store the encoded data, in some examples the distributed data storage system may optimize the fragment size of the erasure coding process. Conventional file systems were originally developed for spinning hard disk drives (HDDs), which have no hardware limitations on the size of write operations. A sector size is determined by the software driver used to read and write the drive. However, flash memory devices, such as for example SSDs, have physical write pages that must be completely overwritten with each write operation. Flash-based devices do not support multiple partial writes to fill a write page. Write pages in a flash device are also organized into erase blocks; typically an erase block is made up of 64 write pages, although other storage architectures may exist or be developed. The entire erase block containing the write page must be erased prior to writing (or rewriting) the page. Each such erasure/rewrite decreases the remaining lifetime of the device; and each page has a limited number of erasures that can be performed before it becomes unreliable. As discussed above, since maintenance and/or replacement of storage assets in space is generally not an option, reducing the usable lifetime of SSDs and other flash storage devices can have a large impact on the lifetime of the satellite.

These factors are generally ignored in terrestrial-only systems, because SSDs can be replaced when their usable capacity is reduced below some threshold, and because SSD controllers already perform some wear leveling of their internal devices.

However, an erasure code that is tailored to the size of the SSD internal flash write pages can significantly reduce the number of write cycles an SSD's internal controller will perform due to each SSD write operation. This is critical to the life of a satellite-based distributed data system that cannot be maintained by replacing SSDs.

Thus, in some examples, a satellite may receive at least a portion of the encoded data set and, using on-board processing resources, perform a second encoding process and distribute the portion of the secondarily encoded data set among the solid state drives on the satellite. In some examples, the second encoding process is a second erasure encoding process that determines the size of the encoded fragments based on the write page size of the target solid state drive(s) on the satellite. In some examples, the encoding process determines the sizes of the encoded fragments by matching the sizes of the encoded fragments to the write page sizes of the target solid state drives.

Optimizing the size of encoded fragments in this manner may extend the lifetime of the solid state drives on the satellite by ensuring that each write to the device consumes a full write page (or close to a full write page, such as 80-90%) thereby minimizing erasures and re-writes.

The above described approach to using optimized erasure encoded fragment sizes is more effective than wear-leveling for prolonging SSD device life, but comes at the cost of higher computational overhead. This trade-off may be less attractive for ground-based storage, since devices on Earth can typically be readily replaced. In space, however, different trade-offs between computational overhead and device life may be appropriate, since satellites cannot readily be accessed for device maintenance and replacement.

In some examples, some or all of the processing required to erasure encode a data set may be executed by terrestrial processing resources to minimize the amount of processing hardware that must be included on the satellite. For example, terrestrial processing resources may encode the full data set and transmit the encoded fragments to one or more satellites for storage. In some examples, all of the encoded fragments may be transmitted to a single satellite, after which selected portions of the encoded fragments may be relayed from the single satellite to one or more additional satellites such that the encoded fragments are distributed across multiple satellites for storage. Furthermore, terrestrial processing systems may perform erasure coding of the data fragments based on the size of the write page of the target satellite storage. This may reduce the computational overhead of the processing system of the satellite, reduce power consumption, and allow for satellite assets without erasure coding processing abilities to be included in the distributed data storage network.

In still other examples, processing hardware within a satellite may be used to perform erasure coding of the received data (which may constitute, in some examples, a second erasure encoding of the same data) and select a fragment size based on the write page size of the SSD's on the satellite.

Another advantage of the satellite based distributed storage systems disclosed herein is that the use of erasure coding allows operators to make a constellation of satellites operational before the entire constellation has been launched into orbit. For example, a data set may be split into m fragments and erasure coded into n fragments, where n>m. As described above, only m erasure encoded fragments are needed to enable recovery of the data. When a constellation or swarm of satellites is being launched, often only a subset of the total number of satellites may be launched at a given time depending on the constraints of the launch system. Accordingly, a distributed data storage system as discussed above may be implemented such that the number m of encoded data fragments needed to recover the data matches the number of satellite assets currently in place. In one example, the constellation of satellites is deemed to be operation when at least m fragments have been transmitted to the one or more satellites of the constellation. As additional satellites are added to the constellation or swarm of satellites, the data may be re-encoded using erasure coding to accommodate the increased satellite-based storage, or additional erasure-coded data fragments may be added to the newly launched satellites. In this way, a constellation of satellites may be made operational much sooner in the launch cycle by using erasure coding. By enabling earlier operation of the constellation of satellites, one can enable revenue generation much earlier in the launch cycle, which may in turn provide additional resources to expand and improve the satellite constellation. In some examples, as discussed above, a hybrid terrestrial/satellite distributed data storage system may be used in combination with these sub-constellations of satellites.

Similarly, an existing or expanding “hive” or “swarm” of small satellites (referred to herein as “smallsats”), which may include microsatellites, cubesatellites (CubeSats), SmallSets, minisatellites, or nanosatellites, may employ an erasure coding based distributed data storage system as discussed above. By using erasure coding on a hive of smallsats, the data fragments may be spread over the large number of small-storage-capacity smallsats such that the total or cumulative storage capacity is increased. In some examples, such a system could operate as discussed above with respect to the systems 200, 300 illustrated in FIGS. 2 and 3 respectively, while in other examples the distributed data storage system may distribute multiple duplicate copies of the n encoded fragments among the smallsats. This may have additional advantages and which may increase reliability and access of the data from the hive of smallsats. For example and without limitation, if m=6 and n=10, terrestrial assets would only need to have a line of sight to at least 6 smallsats at any one time and can recover the data. In some examples, such a small subset of the hive of smallsats could have direct line-of-sight with terrestrial assets many times throughout the day. In another example without limitation, the swarm or hive of satellites may include 100 smallsats, and if there are n=10 erasure-coded fragments, then ten copies of the erasure-coded fragments could be stored in the swarm to enable access to the data by a plurality terrestrial assets located at different geographical positions at the same time. Such an implementation would allow for additional reliability based on the locations of ground stations with line of sight, enable multiple users to access and recover data if they have line of sight to varying subsets of smallsats within the hive throughout the day, and in some cases at all times based on the specific orientation and configuration of the hive of smallsats. In some examples this would enable data to be recovered or accessed even in the event that one or more smallsats are offline due to utilization by other users, other functions, or due to malfunction of the satellite.

The distributed data storage systems of the present disclosure may also employ error detection and correction (EDAC) of transmitted and received signals. In some examples, the EDAC algorithms and functions may include cyclic redundancy check (CRC), checksum, parity data, hash functions, and the like. The use of EDAC algorithms may ensure that transmitted data is correctly received, can initiate re-transmission of corrupted data transmissions if needed, and as a result may reduce the need for recovery of the data using the erasure-coded fragments due to transmission or reception errors.

The distributed data storage systems of the present disclosure may also employ cryptographic processing. In some examples, some erasure encoded fragments may selectively be encrypted using various levels of encryption to provide additional safeguards against access to the data. For example, in some implementations a distributed data storage system may encrypt only a portion of the erasure coded fragments while leaving the remainder of encoded fragments unencrypted. In other examples, a distributed data storage system may encrypt n-m fragments to ensure that data cannot be recovered without access to the encrypted data fragments. Similarly, in some examples a distributed data storage system may encrypt m-1 fragments to ensure data cannot be recovered without access to the encrypted fragments. In still other examples, a distributed data storage system may encrypt some subset of erasure encoded fragments with a low-level of encryption (e.g., Advanced Encryption (AES) Standard encryption, Triple Data Encryption Standard (3DES), RSA encryption standard, and the like) and encrypt other subsets of erasure encoded fragments with a higher level of encryption (e.g., CNSSP-12, CNSSP-15, FIPS 186-2, SHA-256, SHA-384, AES-256, and the like). In some examples, encryption may be performed by satellite processing systems, terrestrial processing systems, or a combination of both.

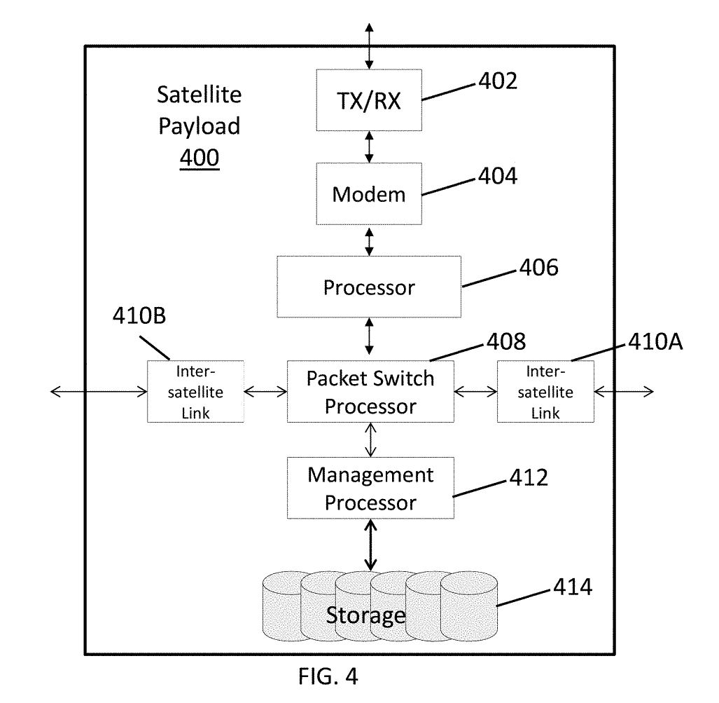

FIG. 4 depicts an exemplary payload 400 for a satellite that may be used for implementing distributed data storage systems of the present disclosure. This exemplary payload may be used within a satellite 202, 302 such as those depicted in FIGS. 2-3, for example. In operation, the payload 400 may receive a data signal, such as an radio frequency (RF) signal, from a terrestrial asset via a transmitter and receiver 402 (e.g., an antenna, antenna array, direct radiating array, optical transceiver module, RF transceiver, and the like) and provide the signal to the modem 404 for demodulation. In some examples, the received data signal may include some or all of the encoded fragments of an erasure encoded data set. In some examples, the data signal may include some or all of a data set that has not yet been erasure encoded. The demodulated signal may be transmitted to the processor block 406. The processor block 406 may, optionally, perform erasure encoding of the received data set, and may optionally perform encryption and decryption of the data fragments. In some examples, a portion of the data set is transmitted via packet switch processor 408 to the management processor 412, which may also include an encoding subsystem, which controls storage in the memory array 414. The memory array 414 may include flash-based storage devices such as solid state drives (SSDs), for example.

In some examples, the management processor 412 may optionally perform erasure encoding to encode the data set (possibly as a second encoding, if the received data was encoded). In some examples, the management processor 412, which may include an encoding subsystem, may select a code size based on the write page size of the storage elements. For example, the management processor may select a code size such that the size of the encoded fragments matches the write page size of the storage element, or such that the size of the encoded fragments is approximately 80-90% of the write page size.

In some examples, some or all of the data set (which may have been encoded on the ground or on the satellite, or may not yet have been encoded) may be provided to the packet switch processor 408, which may, in turn, provide some or all of the received data set to the management processor 412 or transmit some or all of the received data set to another satellite via an inter-satellite link 410A or 410B. Inter-satellite links 410A,B may in some examples be optical links such as laser or other photonic transceivers, an antenna, or an antenna array. The target satellite may receive the transmitted data using a receiver such as another optical link such as a laser or other photonic link, an antenna, or antenna array, for example. In this manner, portions of a received data set (or the corresponding encoded fragments) may be relayed among multiple satellites for implementation of distributed storage.

It is noted that one or more of the components of the exemplary payload discussed above with respect to FIG. 4 can be made radiation tolerant, and/or the exemplary payload can include compensation methods and structures to compensate or correct for radiation effects, as discussed below with respect to radiation considerations. Accordingly, in some examples the exemplary payload 400 may be a radiation-tolerant exemplary payload which includes radiation hardening by design (RHBD), radiation hardening by process (RHBP), and/or system-level radiation mitigation techniques. Similarly, in some examples one or more of the transmitter and receiver 402, modem 404, processor block 406, packet switch processor 408, management processor 412, memory array 414, and inter-satellite links 410 may be a radiation-tolerant transmitter and receiver 402, a radiation-tolerant modem 404, a radiation-tolerant processor block 406, a radiation-tolerant packet switch processor 408, a radiation-tolerant management processor 412, a radiation-tolerant memory array 414, and/or radiation-tolerant inter-satellite links 410.

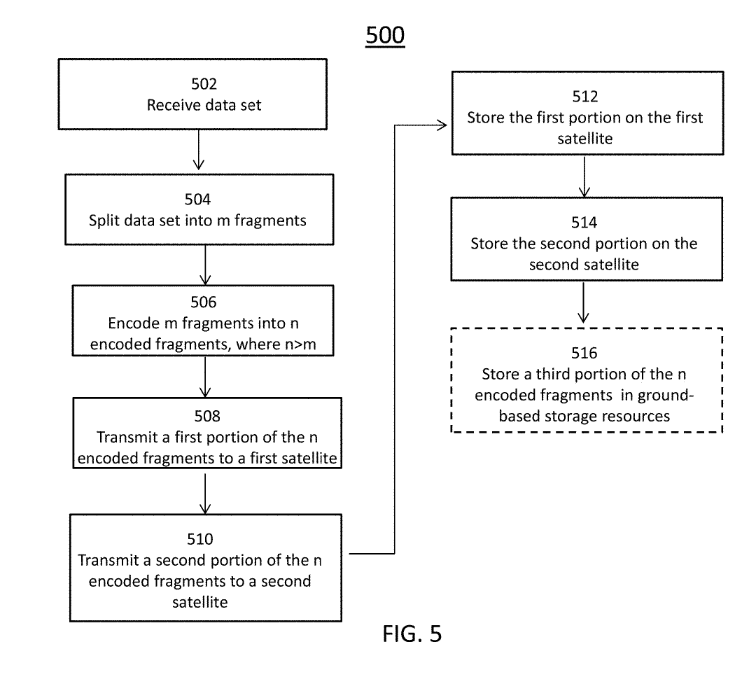

FIG. 5 depicts an exemplary method for implementing distributed satellite-based data storage.

At block 502, a data set is received. In some examples, the data set is received by one or more terrestrial processing subsystems. In some examples, the data set is received by one or more processing subsystems located on one or more satellites.

At block 504, the data set is split into m fragments. In some examples, the data set is split into the fragments by the terrestrial processing subsystem(s) or by a satellite-based processing subsystem(s). In some examples, the number of fragments, m, may be selected to provide a specified level of reliability, or to minimize required processing or storage resources, for example.

At block 506, the m fragments are encoded into n encoded fragments, where n>m. In some examples, the number of encoded fragments, n, is selected based on a desired level of reliability, for example. In some examples, the m fragments are encoded using erasure coding, based on Reed-Solomon codes, Turbo codes, fountain codes, Low Density Parity codes, or other suitable erasure codes. In some examples, the m fragments are encoded using one or more terrestrial processing subsystems. In some examples, the m fragments are encoded using one or more satellite-based processing subsystems.

At block 508, a first portion of the n encoded fragments is transmitted to a first satellite. In some examples, if the fragments were encoded using terrestrial processing subsystem, the first portion of the encoded fragments may be transmitted from Earth to the first satellite for storage. In some examples, if the fragments were encoded using a processing subsystem on one satellite, the first portion of the encoded fragments may be transmitted from the one satellite to the first satellite for storage.

At block 510, a second portion of the n encoded fragments is transmitted to a second satellite. In some examples, if the fragments were encoded using terrestrial processing subsystem, the second portion of the encoded fragments may be transmitted from the ground to the second satellite for storage. In some examples, if the fragments were encoded using a processing subsystem on a first satellite, the second portion of the encoded fragments may be transmitted from the first satellite to the second satellite for storage.

At block 512, the first portion of the n encoded fragments is stored on the first satellite. In some examples, the first portion of the n encoded fragments is stored in a storage subsystem on the first satellite. In some examples, the storage subsystem includes a solid state drive (SSD). In some examples, the storage subsystem includes non-volatile storage, such as NAND flash; NOR flash; 2D NAND technologies including V-NAND (Samsung); 3D XPoint memories including Octane (Intel) and QuantX (Micron); phase-change memory including C-RAM, chalcogenide RAM, PCRAM, PRAM, ferroelectric RAM including FeFRAM and FRAM; magnetoresistive RAM including MRAM; Carbon nanotube based memories including NRAM; and/or memristor based memories.

In some examples, storing the n encoded fragments on the first satellite includes determining a write page size of a target storage device, selecting a code size based on a write page size of a storage device, and encoding using erasure codes the first portion of the encoded fragments based on the selected code size. Such encoding may, in some examples, be a secondary erasure encoding that is performed by a processing subsystem on the first satellite. Thus, each satellite may encode fragments based on the write page size of the storage devices on the satellite.

At block 514, the second portion of the n encoded fragments is stored on the second satellite. In some examples, storing the second portion of the n encoded fragments may include encoding the second portion prior to storage based on a write page size of a storage device on the second satellite, as described above with respect to block 510.

Optionally, at block 516, a third portion of the n encoded fragments is stored in terrestrial storage resources. In some examples, if the m fragments are encoded using a terrestrial processing subsystem, the third portion of the n encoded fragments may be stored at the same or different location as the terrestrial processing subsystem. In some examples, if the m fragments are encoded using a satellite-based processing subsystem, the third portion of the n encoded fragments may be received, by a terrestrial processing subsystem, from the satellite, and stored at a terrestrial storage subsystem in the same or a different location as the terrestrial processing subsystem.

In some examples, the number of fragments stored on the ground is selected such that the data set cannot be reconstructed using only fragments stored in the terrestrial storage system(s). That is, the number of encoded fragments, y, that comprise the third portion of the n encoded fragments is selected to be less than m (where m is the minimum number of fragments required to reconstruct the data set).

In some examples, the total number of fragments stored in the first satellite and second satellite—that is, the total number of fragments in the first portion and second portion—is selected such that the data set can be reconstructed using only the encoded fragments stored in satellite-based storage subsystems. That is, in some examples, the encoded fragments stored on the ground are not required to reconstruct the data set.

The simplified processing subsystem 600 illustrated in FIG. 6 may include a CPU 602, memory 604, and input output (I/O) interface 606. In some examples, the processor 406 or management processor 412 as discussed above with respect to FIG. 4 may include the simplified processing subsystem 600. The CPU 602 may be a microprocessor, an application specific integrated circuit (ASIC), a field programmable gate array (FPGA), and the like. Memory 604 may be volatile or non-volatile memory for use by the CPU 602, including algorithms or software for performing encryption, decryption, erasure encoding and decoding. I/O interface 606 may be substantially any interface for interconnecting the processing subsystem 600 with other components of the satellite and/or terrestrial assets, and may include connections between modules within a circuit as well as connections between components external to the processing subsystem 600. Storage 608 may be communicatively coupled to the memory 604, CPU 602, and I/O interface 606. Storage 608 may include one or more storage devices such as solid state storage devices, hard disk drives, flash-based memory, and the like. Storage 608 may be used to store raw or unencoded data, erasure-encoded data, and encrypted or unencrypted data. When implemented in a satellite, storage 608 may be a solid state disk (SSD) drives or other flash-based storage devices. When implemented in ground-based or terrestrial assets, storage 608 may be hard disk drives (HDDs), solid state disk (SSDs) drives, flash-based storage devices, hybrid storage devices, and the like. In some examples, memory array 414 as discussed above with respect to FIG. 4 may include the storage 608.

It is noted that one or more of the components of the simplified processing subsystem 600 discussed above with respect to FIG. 6 can be made radiation tolerant, and/or the simplified processing subsystem can include compensation methods and structures to compensate or correct for radiation effects, as discussed below with respect to radiation considerations. Accordingly, in some examples the simplified processing subsystem 600 may be a radiation-tolerant simplified processing subsystem 600 which includes radiation hardening by design (RHBD), radiation hardening by process (RHBP), and/or system-level radiation mitigation techniques. Accordingly, in some examples one or more of the CPU 602, memory 604, I/O interface 606, and/or storage 608 may be a radiation-tolerant CPU 602, a radiation-tolerant memory 604, a radiation-tolerant I/O interface 606, and/or a radiation-tolerant storage 608.

### Radiation Considerations

Due to the ionizing radiation environment experienced by electronics operating in satellite applications, it may be desirable for all or portions of the electronics to be radiation hardened or radiation tolerant. This can include any or some combination of electronics that have been radiation hardened by process (RHBP) (having to do with the underlying semiconductor technology regarding how the electronic device is fabricated), by radiation hardened by design (RHBD) (having to do with the physical layout of the circuit elements on the die) or by other means. Radiation tolerance may be determined via test, analysis, or test and analysis of devices whose design was not intentionally optimized for use in an ionizing radiation environment, such as commercial off the shelf (COTS) devices.

The harsh environment faced by a satellite can increase the challenge of designing electronic circuitry. One of the primary environmental risks in a satellite application is associated with the ionizing radiation environment present in space. It should be noted that radiation effects associated with ionizing radiation are also present in terrestrial applications and such radiation effects are generally termed soft errors. The ionizing radiation environment in space includes heavy ions, protons, and neutrons which can impact the normal operation of semiconductor devices via single event effects (SEE), total ionizing dose (TID), and/or displacement damage dose (DDD). The effects of TID and DDD are generally cumulative over the mission duration and impact semiconductor parameters including current leakage. The effects of SEE are generally instantaneous and can impact the operation of the semiconductor circuit. These SEE effects include single event latchup (SEL), single event upset (SEU), single event transient (SET), and single event functional interrupt (SEFI). Mitigation for SEL can be provided via use of a technology such as silicon on insulator (SOD. The effects of SEU, SET, and/or SEFI can include causing a serial communication line (commonly referred to as a lane) to go into an invalid state (an example would be loss of lock) in which valid data is no longer being transmitted or received for an extended period of time. The rate of occurrence of soft errors in terrestrial applications for a typical semiconductor chip design is significantly lower than the rate of occurrence of SEU, SET, and/or SEFI for the same semiconductor chip design in space applications, and therefore soft error caused by radiation effects must be taken into account and mitigated as efficiently and effectively as possible in satellite applications.

The mitigation of SEU, SET, and/or SEFI in semiconductor chip designs for space applications can be performed using a variety of techniques including the selection and optimization of materials and processing techniques in the semiconductor fabrication (radiation hard by process (RHBP)), and by the design and fabrication of specialized structures in the design of the chip which is then fabricated via conventional materials and processes in the semiconductor fabrication process (radiation hard by design (RHBD)). There are additional techniques for providing system level mitigation in systems that include semiconductor chips that are either RHBP, RHBD, or conventional (not specifically optimized for use in an ionizing radiation environment), such SEU, SET, and/or SEFI mitigation techniques are referred to in this application as system level radiation mitigation techniques (SLRMT). In some examples, system level radiation mitigation techniques may comprise algorithms and processes for scrubbing of radiation-affected electronics and storage devices, or may include providing redundant copies of radiation-susceptible electronics and storage devices.

The effective design of electronics systems for use in the space ionizing radiation environment requires that the system design team make effective and efficient use of components that are either RHBP, RHBD, and/or conventional and often includes the use of SLRMT. The optimization of the component selection and SLRMT depends to a large extent on the specific details of the radiation effects that are to be mitigated and the desired level of system radiation tolerance to be obtained. Many SEU, SET, and/or SEFI are generally best mitigated as close as possible, both spatially and temporally, to where the SEE induced event occurred in the component or system level circuit to provide effective and efficient mitigation of such effects. For example, the duration of SET induced in ASIC technology nodes with a feature size <90 nanometers (nm), can be <1 nanosecond, and can be as short as several tens of picoseconds for feature sizes <32 nm. The mitigation of such short duration SET within the same semiconductor package can provide for a more efficient implementation of SET mitigation relative to an approach which spans two of more chips in separate locations within the same system. This efficiency results from the ability to detect and mitigate spatially and/or temporally close to the source of the SEE induced errors.

Radiation test may be accomplished using a beam of charged particles from a particle accelerator where the charged particle beam may include protons and/or heavy ions and the accelerator may be a cyclotron or a linear accelerator. The beam energy in the case of a proton beam may be in the range of 0.1 megaelectron volt (MeV) to over 200 MeV and is typically in the range of approximately ≥1 MeV to either approximately 65 or 200 MeV. The beam in the case of a heavy ion beam may have a linear energy transfer (LET) in the range of 0.1 to over 100 MeV·cm²/mg and is typically in the range of ≥0.5 to approximately 60 to 85 MeV·cm²/mg. The total fluence of particles used in such tests can vary considerably and is often in the range of 10⁶ to over 10¹² particles per cm² at each beam energy in the case of a proton beam and is often in the range of 10² to over 10⁸ particles per cm² at each LET value in the case of a heavy ion beam. The number of radiation induced upsets (SEU), transients (SET), and/or functional interrupts (SEFI) is often expressed as a cross section which relates to the number of observed events in a given area (typically 1 cm²) as a function of the beam fluence. The cross section is no greater than 1.0 and can be smaller than 10⁻¹⁰ cm², it is often in the range of approximately 10⁻² to ≤10⁻¹⁰ cm². A device is generally considered to be radiation tolerant if the number of detected SEU, SET, and/or SEFI is sufficiently small that it will not have a significant impact on the operation of the system or circuit containing one or more instances of that device. Purely as an example and in no way intended to limit the present disclosure, a heavy ion cross section ≤10⁻⁴ cm² at a LET ≥37 MeV*cm²/mg as demonstrated by test and/or analysis is an example of a cross section which may be sufficient to be demonstrate that a given device is radiation tolerant. The heavy ion or proton cross section that is measured or determined by analysis for a device at one or more beam LET values or beam energy values to be considered radiation tolerant may vary considerably and depends in part on the anticipated orbit for the satellite and the extent to which the circuit and/or system containing that device is capable of maintaining the desired operation when a SEU, SET, and/or SEFI occurs.

Furthermore, in addition to ground-based antennas, dishes, gateways, base stations, and the like, terrestrial assets as discussed herein may include high-altitude assets such as drones, unmanned aerial vehicles, piloted aircraft, tethered transceivers, balloons and other lighter-than-air vehicles, which are operating at an altitude less than the 100 km (328,084 ft) above mean sea level on earth (an altitude which may also be referred to as the Karam line).

A person of skill in the art will recognize that various distributions of encoded fragments among satellite-based storage subsystems and terrestrial storage subsystems are possible, depending on desired system reliability, security, and latency. Similarly, the processing required to encode, distribute, and decode fragments may be distributed across terrestrial resources and satellite-based resources in different ways, depending on the available processing resources and required latencies for data retrieval and/or reconstruction, for example. In some examples, it may be desirable to minimize the amount of processing required by the satellites by performing most or all of the processing using terrestrial resources, since satellite hardware and power are typically tightly constrained. Furthermore, a person of ordinary skill in the art would recognize that the several examples discussed above may be used alone or in combination with other examples without departing from the scope of the present disclosure. Some aspects of the examples and method steps discussed above may be omitted or rearranged, and additional steps added, without affecting the operation or departing from the scope of the distributed data storage systems discussed herein. It is anticipated that portions and subsets of the examples discussed above may have specific utility without requiring the provision of every aspect described herein.

While the embodiments of the invention have been illustrated and described in detail in the drawings and foregoing description, such illustration and description are to be considered as examples and not restrictive in character. For example, certain embodiments described hereinabove may be combinable with other described embodiments and/or arranged in other ways (e.g., process elements may be performed in other sequences, with more or fewer steps involved based on the requirements of the application). Accordingly, it should be understood that only example embodiments and variants thereof have been shown and described.

I/we claim:

1. A system for implementing distributed data storage, comprising:
a first satellite of one or more satellites, each of the one or more satellites comprising a receiver configured to receive data, a transmitter configured to transmit data, and a storage device configured to store data;
one or more terrestrial assets comprising a transmitter configured to transmit data, a receiver configured to receive data, and at least one storage device configured to store data; and
a first processing subsystem of one or more processing subsystems, each processing subsystem configured to:
split a data set into m fragments,
encode the m fragments into n encoded fragments, wherein 1<m<n, and wherein the data set can be reconstructed using m of the n encoded fragments, and
transmit a first portion of the n encoded fragments between the at least one terrestrial asset and the first satellite and/or between the first satellite and a second satellite of the one or more satellites, and wherein the one or more terrestrial assets, the first satellite, and/or the second satellite are configured to store the first portion of the n encoded fragments in the storage device of the first satellite or the terrestrial assets.

2. The system according to claim 1, wherein the first satellite is one of a constellation of satellites communicatively coupled to the one or more terrestrial assets, and wherein one or more terrestrial assets is configured to transmit the first portion of the n encoded fragments to the first satellite for storage in the storage device of the first satellite.

3. The system according to claim 2, wherein the constellation of satellites is operational when at least m encoded fragments have been transmitted to the constellation of satellites.

4. The system according to claim 1, wherein the first satellite is one of a constellation of satellites communicatively coupled to the one or more terrestrial assets, and wherein the first satellite is configured to transmit the first portion of the n encoded fragments to the one or more terrestrial assets for storage in the at least one storage device of the one or more terrestrial assets.

5. The system according to claim 1, wherein at least one terrestrial asset is a ground-based asset located on Earth, a ground-based antenna, a ground-based satellite dish, a ground station, a gateway, a balloon, an autonomous aerial vehicle, an unmanned aerial vehicle, a drone, and/or a piloted aircraft.

6. The system according to claim 1, wherein the first portion of the n encoded fragments comprises all of the n encoded fragments, and wherein the first satellite is configured to:
store a first subset of the n encoded fragments in the storage subsystem of the first satellite;
transmit a second subset of the n encoded fragments to a second satellite of the one or more satellites; and
wherein the second satellite is configured to:
receive the second subset of the n encoded fragments, and
store the second subset of the n encoded fragments in the storage device of the second satellite.

7. The system according to claim 6, wherein the first subset and the second subset comprise one or more copies of at least a portion of the n encoded fragments.

8. The system according to claim 1, wherein the first processing subsystem is provided in the first satellite and is configured to split the first portion into at least a first subset and a second subset of n fragments, and wherein the first satellite is configured to transmit the second subset of the n encoded fragments to the second satellite and/or the one or more terrestrial assets.

9. The system according to claim 1, wherein the storage device of the first satellite comprises a solid state device, and wherein the first processing subsystem is provided in the first satellite and further comprises an encoding subsystem configured to:
determine a write page size of the solid state device;
select a code size based on the determined write page size;
perform a second encoding of at least one of the n encoded fragments based on the selected code size; and
store the secondarily-encoded n encoded fragments on the solid state device.

10. The system according to claim 1, wherein the storage device of the first satellite comprises a solid state device, and wherein the first processing subsystem is provided in the one or more terrestrial assets and further comprises an encoding subsystem configured to:
determine a write page size of the solid state device;
select a code size based on the determined write page size;
perform a second encoding of at least one of the n encoded fragments based on the selected code size;
transmit the secondarily-encoded n encoded fragments to the first satellite for storage on the solid state device.

11. The system according to claim 1, wherein the first processing subsystem is further configured to:
receive a data signal comprising at least m encoded fragments from one or more satellites or one or more terrestrial assets; and
reconstruct the data set from the at least m encoded fragments.

12. The system according to claim 1, wherein each of the one or more processing subsystems is configured to perform erasure coding of the data set and/or reconstruction of an erasure-encoded data set.

13. The system according to claim 12, wherein the erasure coding and/or reconstruction is performed using at least one of Reed-Solomon (RS) codes, Tornado codes, fountain codes, turbo codes, and Low Density Parity codes.

14. The system according to claim 1, wherein the first processing subsystem is configured to transmit the first portion between the first and the second satellite using one of a radio-frequency (RF) antenna and/or an optical transceiver module.

15. A method for implementing distributed data storage, comprising:
receiving, by a receiver of one of a first satellite or a first terrestrial asset, a data set;
splitting, by a first processing subsystem of the first satellite or the first terrestrial asset, the data set into m fragments;
encoding, by the first processing subsystem, the m fragments into n encoded fragments, wherein 1<m<n, such that the data set can be reconstructed using at least m of the n encoded fragments;
transmitting, by one of a first satellite transmitter or a first terrestrial asset transmitter, a first portion of the n encoded fragments to the other of the first satellite or the first terrestrial asset;
storing the first portion on at least one storage device of the first satellite or the first terrestrial asset.

16. The method according to claim 15, further comprising:
transmitting, by the first satellite transmitter or the first terrestrial asset transmitter, a second portion of the n encoded fragments to a second satellite; and
storing the second portion of the n encoded fragments on a storage device on the second satellite.

17. The method according to claim 16, further comprising:
storing a third portion, different from the first portion and second portion, of the n encoded fragments on a storage device of the first terrestrial asset.

18. The method according to claim 17, wherein the third portion of the n encoded fragments comprises less than or equal to m-1 fragments.

19. The method according to claim 17, wherein the first portion and second portion of the n encoded fragments comprise less than or equal to m-1 fragments.

20. The method according to claim 15, wherein at least one of the storage devices of the first satellite and/or the terrestrial asset comprises a solid state device, and wherein storing the first portion of the n encoded fragments comprises:
determining, by a first processing subsystem, a write page size of the solid state device;
selecting, by a first processing subsystem, a code size based on the determined write page size;
performing, by an encoding subsystem of the first processing subsystem, a second encoding of the first portion of the n encoded fragments based on the selected code size; and
storing the secondarily encoded first portion of the n encoded fragments on the solid state device.
